(19) United States
(12) Patent Application Publication
(10) Pub. No.: US 2025/0324517 A1
(43) Pub. Date: Oct. 16, 2025

(54) COPPER FOIL COMPOSITE STRUCTURE AND MANUFACTURING METHOD THEREOF

(71) Applicant: NAN YA PLASTICS CORPORATION, Taipei City (TW)

(72) Inventors: Ching-Yao Yuan, Taipei City (TW); Wei-Sheng Cheng, Taipei City (TW); Yu-Chi Hsieh, Taipei City (TW)

(73) Assignee: NAN YA PLASTICS CORPORATION, Taipei City (TW)

(21) Appl. No.: 18/655,351

(22) Filed: May 6, 2024

(30) Foreign Application Priority Data
Apr. 16, 2024 (TW) 113114176

(51) Int. Cl. H05K 3/02; H05K 3/38; H05K 3/46

(52) U.S. Cl. CPC H05K 3/025; H05K 3/384; H05K 3/4688; H05K 2203/0723; H05K 2203/1105

(57) ABSTRACT

Disclosed is a manufacturing method of a copper foil composite structure, including providing a carrier; performing a co-plating process through a copper plating solution and a nitrogen-containing compound to form a copper-nitrogen composite layer on the carrier; and forming a copper foil layer on the copper-nitrogen composite layer. A copper foil composite structure is also disclosed.

### CROSS-REFERENCE TO RELATED APPLICATION

This application claims the priority benefit of Taiwan application serial no. 113114176, filed on Apr. 16, 2024. The entirety of the above-mentioned patent application is hereby incorporated by reference herein and made a part of this specification.

### BACKGROUND

### Technical Field

The present disclosure relates to a copper foil composite structure and a manufacturing method thereof.

### Description of Related Art

In current practice, a release layer is normally adopted in copper foil structures. However, the stability of the release layer will affect the peeling strength in the subsequent process. For example, the inorganic layer in the current release layer is prone to sag during the manufacturing process, resulting in problems such as uneven distribution and uneven peeling strength of the release layer, and the organic layer therein will also cause the peeling strength to increase at high temperatures, making it difficult to separate the carrier from the copper foil.

### SUMMARY

The present disclosure provides a copper foil composite structure and a manufacturing method thereof, which may improve performance in peeling strength.

A manufacturing method of a copper foil composite structure of the present disclosure includes providing a carrier; performing a co-plating process through a copper plating solution and a nitrogen-containing compound to form a copper-nitrogen composite layer on the carrier; and forming a copper foil layer on the copper-nitrogen composite layer.

In an embodiment of the present disclosure, the concentration range of copper ion in the copper plating solution is between 10 g/L and 60 g/L.

In an embodiment of the present disclosure, the copper plating solution includes copper pyrophosphate or copper sulfate.

In an embodiment of the present disclosure, the concentration range of the nitrogen-containing compound is between 1 ppm and 100 ppm.

In an embodiment of the present disclosure, the nitrogen-containing compound includes 5-mercapato-1-phenyl-1H-tetrazole (5-PTZ), 3-amino-triazole (3-AT), benzotriazole (BTA), 5-aminotetrazole (5-ATZ), 5-tolytriazole 5-(5-TTA), 3,5-diamino-1,2,4-triazole, chlorobenzotriazole (5-CLBTA), carboxy benzotriazole (CBTA) or combinations thereof.

In an embodiment of the present disclosure, the current density of the co-plating process is between 1.5ASD and 4.5ASD, the co-plating temperature is between 40° C. and 55° C., and/or the co-plating time is between 10 seconds and 30 seconds.

A copper foil composite structure of the present disclosure includes a carrier, a copper foil layer and a copper-nitrogen composite layer. The copper-nitrogen composite layer is located between the carrier and the copper foil layer.

In an embodiment of the present disclosure, the thickness of the copper-nitrogen composite layer is between 50 nanometers and 200 nanometers, and the thickness of the copper foil layer is between 1 μm and 5 μm.

In an embodiment of the present disclosure, the two opposite surfaces of the copper-nitrogen composite layer are in direct contact with the carrier and copper foil layer respectively.

In an embodiment of the present disclosure, the copper foil composite structure further includes a roughening layer, an anti-oxidation layer, an anti-rust layer and a silicide layer sequentially stacked on the copper foil layer.

Based on the above, in the present disclosure, by forming the highly stable copper-nitrogen composite layer on the surface of the carrier using the co-plating process to form a part of the copper foil composite structure, it is possible to effectively prevent the copper atoms in the carrier and the copper foil layer from bonding to each other in subsequent processes (such as heat treatment, etc.), so that the performance of the copper foil composite structure in peeling strength may be enhanced.

In order to make the above-mentioned features and advantages of the present disclosure more clear and easy to understand, embodiments are given below and described in detail with reference to the attached drawings.

### BRIEF DESCRIPTION OF THE DRAWINGS

FIG. 1 is a partial flow diagram of a manufacturing method of a copper foil composite structure according to an embodiment of the present disclosure.

FIG. 2 is a partial stack diagram of a copper foil composite structure according to an embodiment of the present disclosure.

### DESCRIPTION OF THE EMBODIMENTS

In the following detailed description, for purposes of explanation and not limitation, exemplary embodiments disclosing specific details are set forth in order to provide a thorough understanding of the various principles of the disclosure. It will be apparent, however, to one of ordinary skill in the art, having been benefited from this disclosure, that the present disclosure may be practiced in other embodiments that depart from the specific details disclosed herein. Furthermore, descriptions of commonly-known devices, methods, and materials may be omitted so as not to shift the focus from the description of the various principles of the present disclosure.

The present disclosure will be more thoroughly described with reference to the drawings of this embodiment. However, the present disclosure may also be embodied in various forms and should not be limited to the embodiments described herein.

Unless otherwise defined, all terms (including technical and scientific terms) used herein have the same meaning as commonly understood by one of ordinary skill in the art to which this disclosure belongs.

The term “between” used in this specification to define numerical ranges is intended to cover ranges equal to and between the stated endpoints. For instance, if a size range is between a first value and a second value, the size range may cover the first value, the second value, and any value between the first value and the second value.

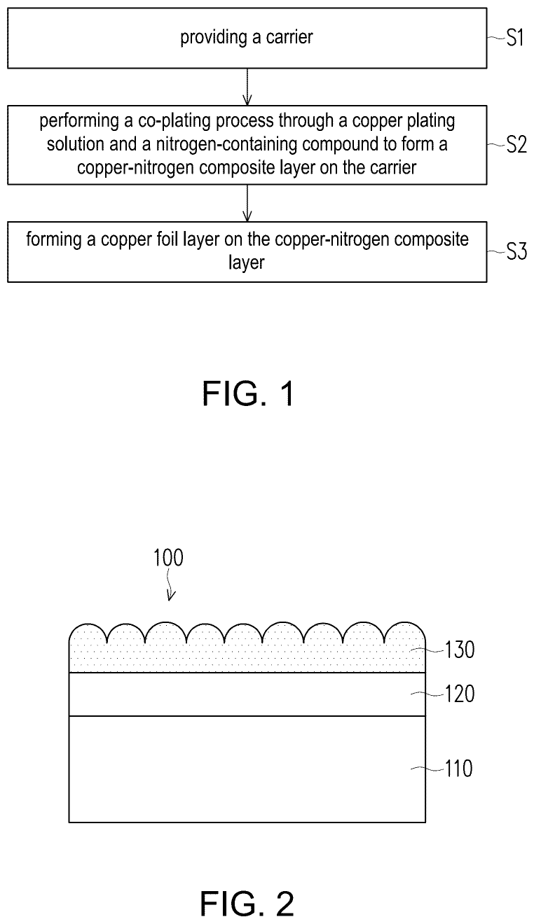

FIG. 1 is a partial flow diagram of a manufacturing method of a copper foil composite structure according to an embodiment of the present disclosure. FIG. 2 is a partial stack diagram of a copper foil composite structure according to an embodiment of the present disclosure.

Referring to FIG. 1 and FIG. 2, the manufacturing method of the copper foil composite structure 100 of this embodiment at least includes the following steps. First, as shown in step S1, a carrier 110 is provided. Next, as shown in step S2, a co-plating process is performed through a copper plating solution and a nitrogen-containing compound to form a copper-nitrogen composite layer 120 on the carrier 110. Then, as shown in step S3, a copper foil layer 130 is formed on the copper-nitrogen composite layer 120. In this way, in the present disclosure, by forming the highly stable copper-nitrogen composite layer 120 on the surface of the carrier 110 using the co-plating process to form a part of the copper foil composite structure 100, it is possible to effectively prevent the copper atoms in the carrier 110 and the copper foil layer 130 from bonding to each other in subsequent processes (such as heat treatment, etc.), so that the performance of the copper foil composite structure 100 in peeling strength may be enhanced.

In some embodiments, the copper-nitrogen composite layer 120 may serve to provide a release interface, so that the pressed structure of the copper foil layer 130 is able to be easily separated from the carrier 110. In the meantime, the copper-nitrogen composite layer 120 may serve a base protection function, and therefore the copper foil composite structure 100 of the present disclosure may omit the use of conventional release layers (inorganic layers and organic layers) and base layers, thereby avoiding the problems of sag as well as uneven distribution of peeling strength. In the meantime, the ease of processing of the co-plating process may simplify the manufacturing process and reduce manufacturing costs (the current release layer is composed of more expensive metal components).

In addition, the performance of the product may be further improved by adjusting the parameter conditions of the co-plating process through the following design, for example.

In some embodiments, the concentration range of copper ion in the copper plating solution is between 10 g/L and 60 g/L (for example, 10 g/L, 20 g/L, 30 g/L, 40 g/L, 50 g/L, 60 g/L or any suitable value between 10 g/L and 60 g/L), but the disclosure is not limited thereto. Here, the concentration of copper ion is calculated by converting the copper content in the compound into grams of copper ions. For example, the copper plating solution includes copper sulfate pentahydrate with a copper content of 25.43%, that is, 100 grams of copper sulfate pentahydrate contains 25.43 grams of copper ions.

In some embodiments, the copper plating solution includes copper pyrophosphate or copper sulfate, but the disclosure is not limited thereto.

In some embodiments, the concentration range of the nitrogen-containing compound is between 1 ppm and 100 ppm (for example, 1 ppm, 10 ppm, 30 ppm, 50 ppm, 70 ppm, 100 ppm or any suitable value between 1 ppm and 100 ppm), but the present disclosure is not limited thereto. Here, the concentration of the nitrogen-containing compound is calculated as 1 ppm of the nitrogen-containing compound is equivalent to adding 1 mg of the nitrogen-containing compound to 1 L of the copper plating solution.

In some embodiments, the nitrogen-containing compound includes 5-mercapato-1-phenyl-1H-tetrazole (5-PTZ), 3-amino-triazole (3-AT), benzotriazole (BTA), 5-aminotetrazole (5-ATZ), 5-tolytriazole (5-TTA), 3,5-diamino-1,2,4-triazole, 5-chlorobenzotriazole (5-CLBTA), carboxy benzotriazole (CBTA) or combinations thereof. The present disclosure is not limited thereto.

In some embodiments, the current density of the co-plating process is between 1.5ASD and 4.5ASD (such as 1.5ASD, 2.5ASD, 3.5ASD, 4.5ASD or any suitable value between 1.5ASD and 4.5ASD), but the present disclosure is not limited thereto.

In some embodiments, the co-plating temperature is between 40° C. and 55° C. (for example, 40° C., 42° C., 44° C., 46° C., 48° C., 50° C. or any suitable temperature between 40° C. and 50° C.), but the present disclosure is not limited thereto.

In some embodiments, the co-plating time is between 10 seconds and 30 seconds (such as 10 seconds, 20 seconds, 25 seconds, 30 seconds or any suitable time length between 10 seconds and 30 seconds), but the present disclosure is not limited thereto.

In some embodiments, a high-temperature pressing process will be adopted in the manufacturing process of the copper foil composite structure 100, and the copper-nitrogen composite layer 120 of the present disclosure may still maintain better stability during the process, that is, temperature (room temperature (e.g., 25° C.) or high temperature (e.g., temperature greater than 350° C.)) will not have significant adverse effects on the copper-nitrogen composite layer 120 of the present disclosure, but the disclosure is not limited thereto.

In some embodiments, products are normally required to have thin lines and high-frequency signal transmission, and therefore the copper foil layer 130 should have low roughness (for example, Rz is less than 0.8 μm) and/or thinning design (for example, the thickness is between 1 μm and 5 μm). Due to limitations in mechanical properties, the above designs are often liable to wrinkles and tears during transportation. The use of the stacked design of the carrier 110, the copper-nitrogen composite layer 120 and the thinned copper foil layer 130 of the present disclosure may reduce the probability of the aforementioned problems, but the present disclosure is not limited thereto.

In some embodiments, the co-plating process and the pressing process may allow the two opposite surfaces of the copper-nitrogen composite layer 120 to be in direct contact with the carrier 110 and the copper foil layer 130, respectively, to further reduce the probability of the aforementioned problems, but the disclosure is not limited thereto.

In some embodiments, in the manufacturing process, a copper foil or aluminum foil with a thickness of 18 μm or more is used as the carrier 110 to further reduce wrinkles and tears during transportation, while providing sufficient mechanical strength in the subsequent pressing process (such as laminating the thinned copper foil layer 130 to the prepreg material). The carrier 110 may be torn off in an appropriate manner after the pressing process, which is not limited by the present disclosure.

In some embodiments, the thickness of the copper-nitrogen composite layer 120 is between 50 nanometers and 200 nanometers (for example, 50 nanometers, 100 nanometers, 150 nanometers, 200 nanometers, or any suitable value between 50 nanometers and 200 nanometers), so as to provide better protection while reducing the probability of adversely affecting the thickness of the electroplating of the copper foil layer 130, but the present disclosure is not limited thereto.

In some embodiments, a pickling process is performed before step S1, wherein the pickling process is performed by, for example, cleaning the carrier 110 with sulfuric acid (e.g., a concentration of 10%) to remove surface oxides, but the disclosure is not limited thereto.

In some embodiments, after step S3, the copper foil composite structure 100 may further include a roughening layer, an anti-oxidation layer, an anti-rust layer and/or a silicide layer (not shown) sequentially stacked on the copper foil layer 130.

In some embodiments, the roughening layer is electroplated with a copper plating solution, the copper concentration of the plating solution is between 5 g/L and 15 g/L, and the concentration of sulfuric acid is between 60 g/L and 90 g/L. Pulse current is used as energy supply, and the thickness range is between 0.5 μm and 1.5 μm, but the disclosure is not limited thereto.

In some embodiments, the anti-oxidation layer is formed of a plating solution containing nickel ions and zinc ions, wherein the concentration of zinc ion is between 0 g/L and 8 g/L, the concentration of nickel ion is between 0.5 g/L and 2 g/L, and the thickness range is between 5 nanometers and 10 nanometers, but the disclosure is not limited thereto.

In some embodiments, the anti-rust layer is a chromic acid-impregnated layer, wherein the potassium dichromate concentration ranges from 0.8 g/L to 1.5 g/L, and the thickness ranges from 5 nanometers to 10 nanometers, but the present disclosure is not limited thereto.

In some embodiments, the silicide layer is formed by spraying or impregnated with silane, wherein the silane selected is amino silane (3-aminopropyltrimethoxysilane), the concentration thereof is between 1 g/L and 1.5 g/L, and the thickness ranges from 5 nanometers to 10 nanometers, but the disclosure is not limited thereto.

It should be noted that the above numerical ranges, specific types and related details are not used to limit the present disclosure. The relevant conditions may be adjusted according to actual design requirements, and any implementation that is performed by forming the copper-nitrogen composite layer 120 on the carrier 110 using the co-plating process through the copper plating solution and the nitrogen-containing compound belongs to the scope to be protected by the present disclosure. In addition, the actual operation means of the co-plating process, pickling process, etc. may be any suitable content that is familiar to those skilled in the art, and will not be described again here.

The following examples and comparative examples are listed to illustrate the effects of the present disclosure, but the scope of the present disclosure is not limited to the scope of the examples.

The copper foil composite structures manufactured in each of the examples and comparative examples were evaluated according to the following method.

Peeling strength at room temperature: the roughening layer was attached to the glass plate in the manner of facing down with a test width of 1.27 cm, and the peeling strength between the carrier and the copper foil layer was tested with a tensile testing machine; peeling strength at 200° C.: the copper foil layer and the prepreg material were thermally pressed at 200° C. with a test width of 2.50 cm, and the peeling strength between the carrier and the copper foil layer was tested with a tensile testing machine; peeling strength at 390° C.: after baking the ultra-thin copper foil at 390° C. for 5 minutes, the roughening layer was attached to the glass plate in the manner of facing down with a test width of 1.27 cm, and the peeling strength between the carrier and the copper foil layer was tested with a tensile testing machine.

Examples 1 to 3 and Comparative Example 1 were produced in the following manner.

### Example 1

The copper foil composite structure in Example 1 was formed by sequentially stacking a carrier (with a thickness of 18 μm and a material of copper foil), a copper-nitrogen composite layer (with a thickness of 108 nanometers), a copper foil layer (with a thickness of 3 μm), a roughening layer (copper nodule particles), an anti-oxidation layer (with a thickness of 6 nanometers and a material of nickel-zinc alloy), an anti-rust layer (with a thickness of 5 nanometers and a material of chromium-containing protective layer) and a silicide layer (with a thickness of 5 nanometers and a material of aminosiloxane). The conditions of the co-plating process for forming the copper-nitrogen composite layer were as follows: the concentration of copper ion in the copper plating solution was 20 g/L, the copper plating solution was sulfuric acid copper plating solution, the concentration of the nitrogen-containing compound was 25 ppm, the nitrogen-containing compound was 5-ATZ, the current density was 2ASD, the co-plating temperature was 45° C., and the co-plating time was 15 seconds.

### Example 2

The copper foil composite structure in Example 2 was formed by sequentially stacking a carrier (with a thickness of 18 μm and a material of copper foil), a copper-nitrogen composite layer (with a thickness of 144 nanometers), a copper foil layer (with a thickness of 3 μm), a roughening layer (copper nodule particles), an anti-oxidation layer (with a thickness of 5 nanometers and a material of zinc metal layer), an anti-rust layer (with a thickness of 5 nanometers and a material of chrome layer) and a silicide layer (with a thickness of 5 nanometers and a material of aminosiloxane). The conditions of the co-plating process for forming the copper-nitrogen composite layer were as follows: the concentration of copper ion in the copper plating solution was 10 g/L, the copper plating solution was pyrophosphate copper plating solution, the concentration of the nitrogen-containing compound was 15 ppm, the nitrogen-containing compound was 3-AT, the current density was 2ASD, the co-plating temperature was 45° C., and the co-plating time was 20 seconds.

### Example 3

The copper foil composite structure in Example 3 was formed by sequentially stacking a carrier (with a thickness of 18 μm and a material of copper foil), a copper-nitrogen composite layer (with a thickness of 180 nanometers), a copper foil layer (with a thickness of 3 μm), a roughening layer (copper nodule particles), an anti-oxidation layer (with a thickness of 5 nanometers and a material of nickel zinc metal layer), an anti-rust layer (with a thickness of 5 nanometers and a material of chrome layer) and a silicide layer (with a thickness of 5 nanometers and a material of aminosiloxane). The conditions of the co-plating process for forming the copper-nitrogen composite layer were as follows: the concentration of copper ion in the copper plating solution was 40 g/L, the copper plating solution was pyrophosphate copper plating solution, the concentration of the nitrogen-containing compound was 10 ppm, the nitrogen-containing compound was CBTA, the current density was 2.5ASD, the co-plating temperature was 45° C., and the co-plating time was 25 seconds.

### Comparative Example 1

Comparative Example 1 is similar to Example 1, except that the copper-nitrogen composite layer was replaced with the conventional release layer and base layer (commercially available model NPUE).

Based on the results in Table 1, it may be concluded that the peeling strength of Examples 1 to 3 having the copper-nitrogen composite layer of the present disclosure is less than the peeling strength of Comparative Example 1. For example, the peeling strength of Example 1 may be about 2 times less at room temperature, and even be about 3 times less at high temperatures. Therefore, the copper foil composite structure of the present disclosure indeed has improved performance in peeling strength.

TABLE 1

| | Peeling strength (gf/cm) | | |
|---|---|---|---|
| | Room temperature | 200° C. | 390° C. |
| Comparative | 12.5 | 18.4 | 29.5 |
| Example 1 | | | |
| Example 1 | 6.8 | 8.1 | 10.8 |
| Example 2 | 5.5 | 10.5 | 15.2 |
| Example 3 | 6.3 | 7.6 | 9.4 |

To sum up, in the present disclosure, by forming the highly stable copper-nitrogen composite layer on the surface of the carrier using the co-plating process to form a part of the copper foil composite structure, it is possible to effectively prevent the copper atoms in the carrier and the copper foil layer from bonding to each other in subsequent processes (such as heat treatment, etc.), so that the performance of the copper foil composite structure in peeling strength may be enhanced.

Although the present disclosure has been disclosed above through embodiments, it is not intended to limit the present disclosure. Anyone with ordinary knowledge in the technical field can make some modifications and refinement without departing from the spirit and scope of the present disclosure, so the scope to be protected by the present disclosure shall be determined by the appended claims.

What is claimed is:

1. A manufacturing method of a copper foil composite structure, comprising:
providing a carrier;
performing a co-plating process through a copper plating solution and a nitrogen-containing compound to form a copper-nitrogen composite layer on the carrier; and
forming a copper foil layer on the copper-nitrogen composite layer.

2. The manufacturing method of the copper foil composite structure according to claim 1, wherein a concentration range of a copper ion in the copper plating solution is between 10 g/L and 60 g/L.

3. The manufacturing method of the copper foil composite structure according to claim 1, wherein the copper plating solution comprises copper pyrophosphate or copper sulfate.

4. The manufacturing method of the copper foil composite structure according claim 1, wherein a concentration range of the nitrogen-containing compound is between 1 ppm and 100 ppm.

5. The manufacturing method of the copper foil composite structure according to claim 1, wherein the nitrogen-containing compound comprises 5-mercapato-1-phenyl-1H-tetrazole (5-PTZ), 3-amino-triazole (3-AT), benzotriazole (BTA), 5-aminotetrazole (5-ATZ), 5-tolytriazole (5-TTA), 3,5-diamino-1,2,4-triazole, 5-chlorobenzotriazole (5-CLBTA), carboxy benzotriazole (CBTA) or combinations thereof.

6. The manufacturing method of the copper foil composite structure according to claim 1, wherein a current density of the co-plating process is between 1.5ASD and 4.5ASD, a co-plating temperature is between 40° C. and 55° C., and/or a co-plating time is between 10 seconds and 30 seconds.

7. A copper foil composite structure, comprising:
a carrier;
a copper foil layer; and
a copper-nitrogen composite layer, located between the carrier and the copper foil layer.

8. The copper foil composite structure according to claim 7, wherein a thickness of the copper-nitrogen composite layer is between 50 nanometers and 200 nanometers, and a thickness of the copper foil layer is between 1 μm and 5 μm.

9. The copper foil composite structure according to claim 7, wherein two opposite surfaces of the copper-nitrogen composite layer are in direct contact with the carrier and copper foil layer respectively.

10. The copper foil composite structure according to claim 7, further comprising a roughening layer, an anti-oxidation layer, an anti-rust layer and a silicide layer sequentially stacked on the copper foil layer.
